(19) United States
(12) Patent Application Publication
(10) Pub. No.: US 2026/0333901 A1
(43) Pub. Date: Oct. 22, 2026

(54) MULTIPLE WAVELENGTH BAND LIGHT SENSOR DEVICE

(71) Applicant: Taiwan Semiconductor Manufacturing Company, Ltd., Hsinchu (TW)

(72) Inventors: Hsiang-Lin Chen, Hsinchu County (TW); Yi-Shin Chu, Hsinchu City (TW); Yin-Kai Liao, Taipei City (TW); Sin-Yi Jiang, Hsinchu City (TW); Sung-Wen Huang Chen, Nantou County (TW)

(21) Appl. No.: 19/720,997

(22) Filed: Jun. 26, 2026

Related U.S. Application Data
(62) Division of application No. 18/346,544, filed on Jul. 3, 2023.

(51) Int. Cl. H10F 39/00; H10F 39/18

(52) U.S. Cl. CPC H10F 39/8027; H10F 39/014; H10F 39/024; H10F 39/182; H10F 39/184; H10F 39/8063

(57) ABSTRACT

Some embodiments relate to an integrated circuit light sensor device. The integrated circuit light sensor device includes a semiconductor substrate, as well as a plurality of first light-absorption regions and a plurality of second light-absorption regions located in the semiconductor substrate. Each of the first light-absorption regions includes an implantation region of the semiconductor substrate. The implantation region and the semiconductor substrate form at least a portion of a corresponding one of a plurality of first photodetectors for a first light wavelength band. Each of the second light-absorption regions includes a semiconductor material different from the semiconductor substrate. The semiconductor material forms at least a portion of a corresponding one of a plurality of second photodetectors for a second light wavelength band different from the first light wavelength band.

### REFERENCE TO RELATED APPLICATION

This Application is a Divisional of U.S. application Ser. No. 18/346,544, filed on Jul. 3, 2023, the contents of which are hereby incorporated by reference in their entirety.

### BACKGROUND

Light sensor modules (e.g., camera modules) are typically employed in a variety of electronic devices (e.g., smartphones, web cameras, tablet computers, laptop computers, and the like) to capture optical images, such as two-dimensional visible images. Such modules typically include an integrated circuit light sensor device, a lens assembly including one or more lenses, and supporting electronics (e.g., interface electronics, a digital signal processor (DSP), and so on).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of some embodiments of a light sensor module, including a multiple wavelength band light sensor integrated circuit (IC), according to the present disclosure.

FIG. 2 illustrates a plan view of a sub-pixel layout of some embodiments of a multiple wavelength band light sensor IC.

FIG. 3A illustrates a plan view of a sub-pixel configuration of a single pixel of some embodiments of the multiple wavelength band light sensor IC of FIG. 2.

FIG. 3B illustrates a cross-sectional view of some embodiments of the single pixel depicted in FIG. 3A.

FIGS. 4A-4O illustrate cross-sectional views of some embodiments of a semiconductor structure for a multiple wavelength band light sensor IC at various stages of manufacture.

FIG. 5 illustrates a methodology of forming a multiple wavelength band light sensor IC in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A conventional light sensor module (e.g., a camera module, a complementary metal-oxide semiconductor (CMOS) image sensor (CIS), or the like) typically includes a lens assembly that is optically aligned or coupled with a light sensor IC such that light received by the lens assembly is directed and/or focused on the light sensor IC. Supporting electronics within the light sensor module may then facilitate retrieval and possible processing of data indicative of the amount of light received at various locations about the light sensor IC. As employed herein, the term “light” may apply to both visible and invisible (e.g., infrared, ultraviolet, etc.) wavelength bands of the electromagnetic spectrum.

Typically, a light sensor IC may be limited to sensing a particular wavelength band of light (e.g., a portion of the light spectrum that is visible to the human eye). In some cases, this limitation may be due to different semiconductor materials or configurations being more suitable for different light wavelength bands. For example, a relatively thick silicon substrate may be advantageous for photo-induced electron transfer (PET) in a short-wavelength infrared (SWIR) sensor IC, but is less useful for PET in a visible light (red-green-blue, or RGB) sensor IC. On the other hand, germanium, which provides a lower energy bandgap than silicon, may be suitable for a SWIR sensor IC, in which sensitivity is of significant importance, but may also induce an unacceptably high dark current (e.g., electrical current supplied in the absence of photons) and inordinate number of white pixels in a visible light sensor IC. Consequently, multiple light sensor modules, or a light sensor module with multiple light sensor ICs, lens assemblies, and the like, may be required to allow sensing of light in multiple wavelength bands.

To address these issues, the present disclosure provides some embodiments of a multiple wavelength band light sensor IC that may integrate multiple semiconductor materials into a single semiconductor substrate. In some embodiments, such a sensor IC may be deployed in a light sensor module with a single lens assembly and associated supporting electronics, thereby possibly reducing the overall cost and physical footprint of a light sensing solution.

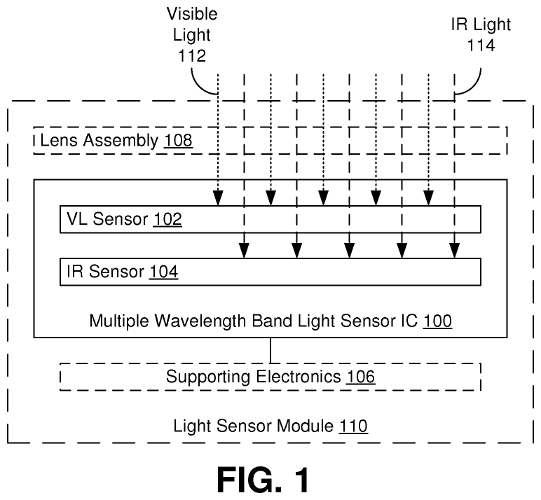

FIG. 1 illustrates a block diagram of some embodiments of a light sensor module 110, including a multiple wavelength band light sensor IC 100, according to the present disclosure. Hereinafter, the multiple wavelength band light sensor IC 100 may also be referred to as the light sensor IC 100 for brevity. In addition to the light sensor IC 100, the light sensor module 110 may include a lens assembly 108 (e.g., one or more lenses) that is configured to receive and direct light toward the light sensor IC 100. The light sensor module 110 may also include supporting electronics 106 (e.g., a digital signal processor (DSP), interfacing circuitry, and so on) to allow the capture and retrieval of sensor data from the light sensor IC 100.

The light sensor IC 100, as shown in FIG. 1, may include a visible light (VL) sensor 102 that is sensitive to visible light 112 and an infrared (IR) sensor 104 that is sensitive to IR light 114 via the lens assembly 108. In some embodiments, the IR sensor 104 may be adapted to sense short-wavelength IR (SWIR) light. In some embodiments, each of the VL sensor 102 and the IR sensor 104 may include a number of separate subpixels (e.g., organized as a two-dimensional array) distributed throughout. Further, groups of subpixels may organized into pixels, with each pixel being associated with a particular portion of an image being captured by the VL sensor 102 and the IR sensor 104.

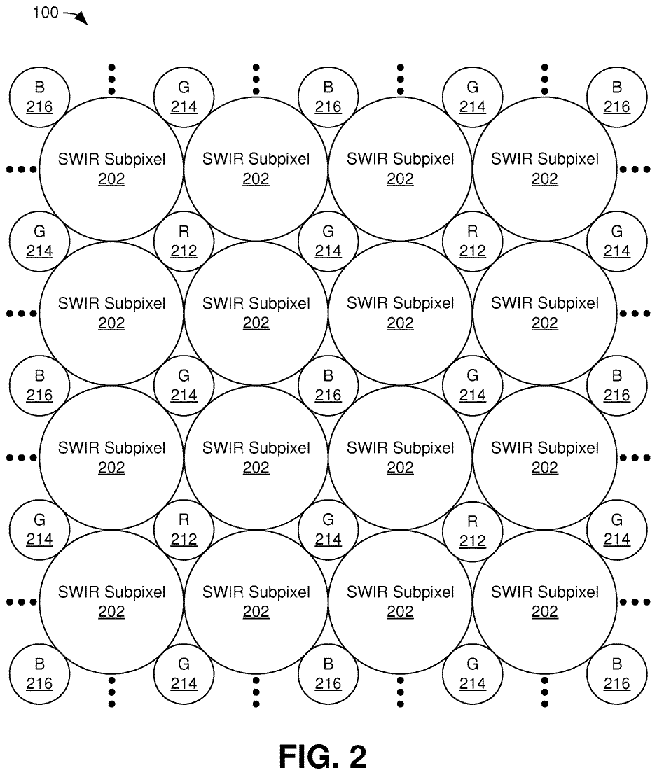

FIG. 2 illustrates a plan view of a sub-pixel layout of some embodiments of the multiple wavelength band light sensor IC 100. As illustrated in FIG. 2, the light sensor IC 100 may include a plurality of SWIR subpixels 202 interspersed with a plurality of VL subpixels that include red (R) subpixels 212, green (G) subpixels 214, and blue (B) subpixels 216. Each of the plurality of VL subpixels 212, 214, and 216 is configured to be sensitive to capture a bandwidth of visible light encompassing its assigned color. In some embodiments, the plurality of SWIR subpixels 202 and the plurality of VL subpixels 212, 214, and 216 are each configured as a two-dimensional array (e.g., in multiple rows and columns) to provide a corresponding two-dimensional image. Further, the two arrays may be slightly offset from each other such that the SWIR subpixels 202 and the VL subpixels 212, 214, and 216 do not overlap in a plan view. Other arrangements of the SWIR subpixels 202 and the VL subpixels 212, 214, and 216 may be employed in other embodiments. In addition, while each of the SWIR subpixels 202 and the VL subpixels 212, 214, and 216 possesses a substantially circular shape in a plan view, other shapes, such as square, rectangular, polygonal, and so on, in a plan view may also be used for the SWIR subpixels 202 and the VL subpixels 212, 214, and 216 in other embodiments.

In some embodiments, each SWIR subpixel 202 may be larger than a corresponding VL subpixel 212, 214, and 216 (e.g., to compensate for a lower quantum efficiency (QE) of a SWIR subpixel 202 relative to the QE of a VL subpixel 212, 214, and 216). In some embodiments, as shown in FIG. 2, each SWIR subpixel 202 may be closely positioned to each adjacent SWIR subpixel 202 in a row direction and a column direction. Such configuration may thus allow each VL subpixel 212, 214, and 216 to be located among each two-by-two group of SWIR subpixels 202 without overlap, as depicted in FIG. 2. In some embodiments, a width or diameter of each SWIR subpixel 202 may range from 1 micron (μm) to 20 μm, and each VL subpixel 212, 214, and 216 may range from 0.1 μm to 2 μm. Also, in some embodiments, the ratio of the diameter of each SWIR subpixel 202 to the diameter of each VL subpixel 212, 214, and 216 may range from approximately 5:1 to approximately 1.5:1, and in some cases may be approximately 2.4:1.

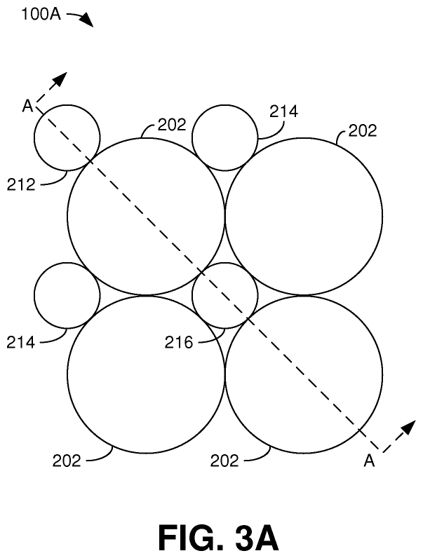

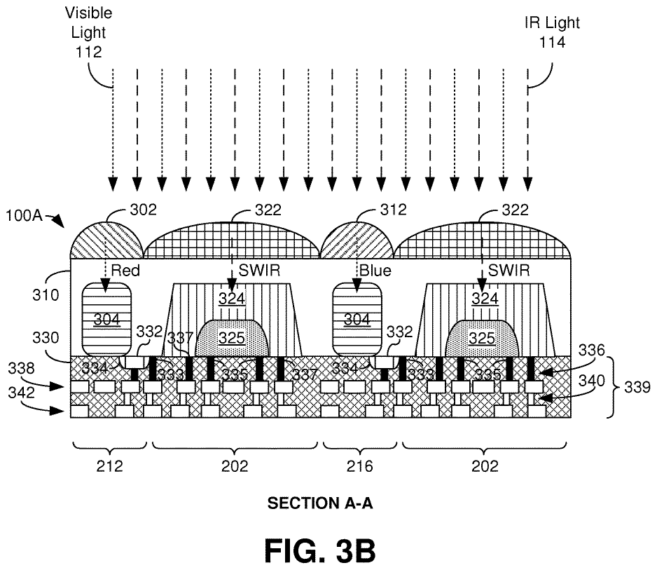

FIG. 3A illustrates a plan view of a sub-pixel configuration of a single pixel 100A of some embodiments of the multiple wavelength band light sensor IC 100 of FIG. 2. The single pixel 100A includes four SWIR subpixels 202 in a two-by-two configuration, as well as four VL subpixels 212, 214, and 216 (e.g., one red subpixel 212, two green subpixels 214, and one blue subpixel 216) in another two-by-two configuration. Also, in some embodiments, the pair of two-by-two configurations may be offset from each other, as depicted in FIG. 3A, such that the SWIR subpixels 202 and the VL subpixels 212, 214, and 216 do not overlap and are contained within some area associated with the single pixel 100A.

In some embodiments, two green subpixels 214, as opposed to one red subpixel 212 and one blue subpixel 216, may be used in the single pixel 100A to mimic the increased sensitivity of the human eye to the green portion of the visible light spectrum.

FIG. 3B illustrates a cross-sectional view, shown along section line A-A of FIG. 3A, of some embodiments of the single pixel 100A of the multiple wavelength band light sensor IC 100. Consequently, the cross-sectional view includes two SWIR subpixels 202, a red subpixel 212, and a blue subpixel 216. In some embodiments, green subpixels 214 of the single pixel 100A that are not shown in FIG. 3B may have a structure similar to that of either or both of a red subpixel 212 and a blue subpixel 216.

As configured in FIG. 3B, the single pixel 100A of the light sensor IC 100 may include a filter/lens (e.g., in the form of a micro-lens) for each subpixel and attached (e.g., with an adhesive) to a backside surface of a semiconductor substrate 310. In some embodiments, each micro-lens is positioned, in a plan view of the semiconductor substrate 310, to define the area of its associated subpixel (e.g., as shown in FIG. 3A). For example, a SWIR micro-lens 322 may be employed for an associated SWIR subpixel 202, a red micro-lens 302 may be employed for an associated red subpixel 212, and a blue micro-lens 312 may be employed for an associated blue subpixel 216. In addition, not shown in FIG. 3B, the single pixel 100A may also include a green lens for each green subpixel 214. In some embodiments, each micro-lens 302, 312, and 322 may be configured to direct light (e.g., light received from a lens assembly 108 of FIG. 1) to its associated subpixel. As depicted in FIG. 3B, the micro-lenses 302, 312, and 322 may be spherical micro-lenses, although other types of lenses are also possible. Further, in some embodiments, each micro-lens 302, 312, and 322 may be configured to filter the received light to pass light associated with its associated subpixel. For example, micro-lens 302 may be configured to pass wavelengths of a red portion of the electromagnetic spectrum, micro-lens 312 may be configured to pass wavelengths of a blue portion of the spectrum, and micro-lens 322 may be configured pass wavelengths of a SWIR portion of the spectrum. In other embodiments, the filtering and lens functions may be separated into corresponding filtering and lens structures.

In some embodiments, based on the operation of the micro-lenses, the red wavelengths of the visible light 112 will be directed toward a photodetector associated with each red subpixel 212, the green wavelengths of the visible light 112 will be directed toward a photodetector associated with each green subpixel 214, the blue wavelengths of the visible light 112 will be directed toward a photodetector associated with each blue subpixel 216, and the SWIR wavelengths of the IR light 114 will be directed toward a photodetector associated with each SWIR subpixel 202. Accordingly, below each micro-lens 302, 312, and 322, as illustrated in FIG. 3B, is located a semiconductor photodetector structure (e.g., a photodiode) incorporated within the semiconductor substrate 310.

In some embodiments, each VL subpixel 212, 214, and 216 may include a light-absorption region that includes an implantation region 304 that, in combination with the semiconductor substrate 310, forms a photodiode that is sensitive to a visible light wavelength band (e.g., a band of visible light 112). For example, the semiconductor substrate 310 may be p-doped silicon, and the implantation region 304 may be a portion of the semiconductor substrate 310 that has been implanted or doped with ions to create an n-doped region. In some embodiments, the photodiode and associated photodiode junction generated by the formation of the implantation region 304 may be a PN photodiode (e.g., a “pinned” photodiode) that is sensitive to photons of visible light.

Also, in some embodiments, each SWIR subpixel 202 may include a light-absorption region that includes a semiconductor material 324 that is different from the semiconductor substrate 310 and that forms a photodiode that is sensitive to a SWIR wavelength band (e.g., a band of IR light 114). For example, a portion of the semiconductor substrate 310 may be etched and subsequently filled with the different semiconductor material 324 (e.g., p-doped germanium). In some examples, the etched region or cavity for the different semiconductor material 324 may have an angled side, as shown in FIG. 3B. Thereafter, the different semiconductor material 324 filling an associated cavity may be implanted or doped with ions to create at least an n-doped implantation region 325. In some embodiments, the photodiode and associated photodiode junction generated by the formation of the different semiconductor material 324 and associated implantation region 325 may be a PIN photodiode that is sensitive to SWIR light.

Based on the various structures incorporated in the semiconductor substrate 310 (e.g., the implantation region 304, as well as the different semiconductor material 324 and associated implantation region 325), the single semiconductor substrate 310 (and thus, a single light sensor IC 100) may incorporate at least two pluralities of photodetectors, where each plurality of photodetectors may be sensitive to a different light wavelength band of light.

In some embodiments, the implantation region 304, the different semiconductor material 324, and the associated implantation region 325 may be circular in shape in a plan view (e.g., in the direction from which the visible light 112 and IR light 114 may be generally received). Such a shape may align with a generally circular shape for the micro-lenses 302, 312, and 322 discussed above. However, other shapes for the different semiconductor material 324 and the associated implantation region 325 may also be possible in other embodiments.

In some embodiments, the implantation region 304, the different semiconductor material 324, and the associated implantation region 325 may be formed via the frontside surface of the semiconductor substrate 310. Accordingly, in some embodiments, the implantation region 304, the different semiconductor material 324, and the associated implantation region 325 are accessible via the frontside surface (e.g., by way of semiconductor layers, contacts, and the like) to facilitate control of the photodetectors within the semiconductor substrate 310.

For example, in some embodiments, a gate structure 332 and associated sidewall spacer 334 may be formed over the semiconductor substrate 310 adjacent the implantation region 304 for the associated visible light photodiode. In some embodiments, the gate structure 332 may be made of polycrystalline silicon (poly-Si). Also, in some embodiments, the gate structure 332 may be controlled as a transfer gate to transfer charge collected in the photodiode over some period of time to a measurement node via a measurement contact 333 adjacent the gate structure 332.

In some embodiments, an interconnect structure 339 is disposed over the frontside surface. The interconnect structure 339 includes contacts 335 and 337, which may be formed over the different semiconductor material 324 and the associated implantation region 325 to function as a cathode and anode, respectively, for the associated SWIR photodiode. In FIG. 3B, contacts 335 and 337 may be at least partially circular in a plan view, whereby contacts 335 may be diametrically opposed sides of a single circular cathode, while contacts 337 may be diametrically opposed sides of a single circular anode. This circular shape may substantially correspond with a circular semiconductor material 324 and associated implantation region 325. While FIG. 3B depicts circular structures for contacts 335 and 337, other shapes for contacts 335 and 337 are possible in other embodiments. For example, for a rectangular semiconductor material 324 and associated implantation region 325, as seen in a plan view, contacts 337 may be separate contacts positioned at opposing ends of the different semiconductor material 324, and contacts 335 may be separate contacts positioned at opposing ends of the associated implantation region 325.

In some embodiments, contacts 336, including contacts 333, 335, and 337, may be formed in a layer of dielectric material 330 to couple the various regions within semiconductor substrate 310 to one or more metal structures 338. Also, in some embodiments, one or more additional metal structures 342 may be coupled to one or more metal structures 338 by way of vias 340. Metal structures 338 and 342, in some embodiments, may couple the photodetectors in semiconductor substrate 310 to supporting circuitry (e.g., supporting electronics 106 of FIG. 1) of a light sensor module (e.g., light sensor module 110 of FIG. 1) to retrieve and process sensor data provided by the various photodiodes. For example, some elements of the metal structures 338 and 342 may serve as row and column select lines for accessing specific ones of the photodiodes.

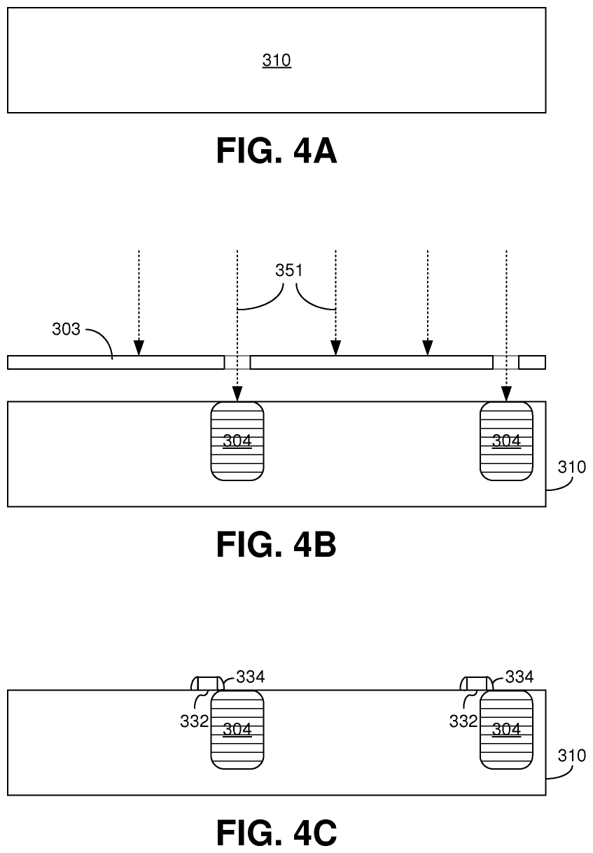

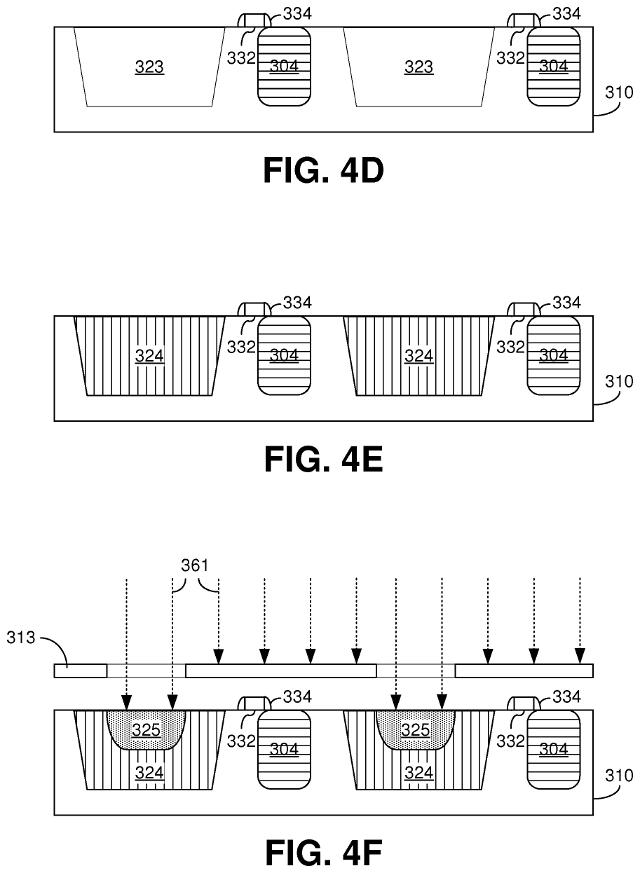

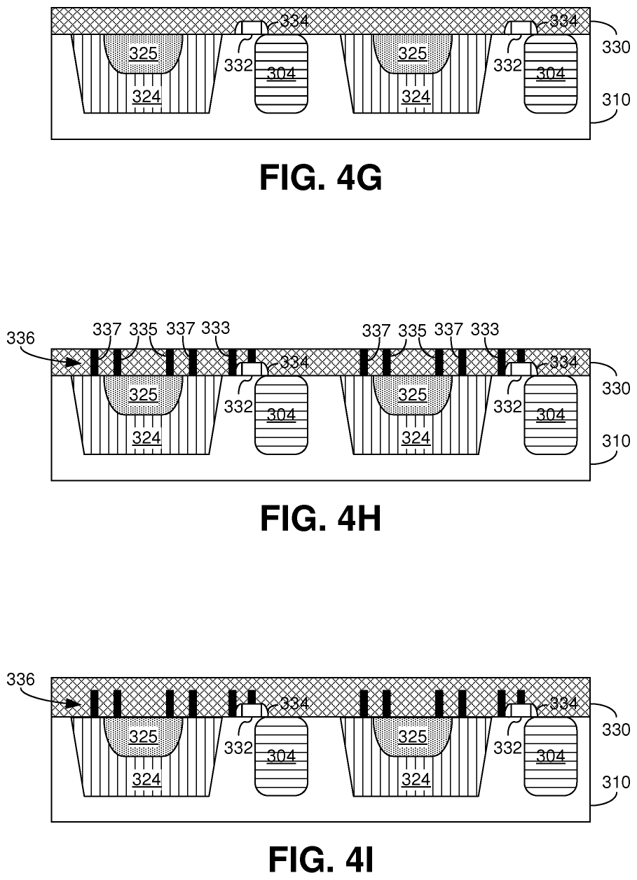

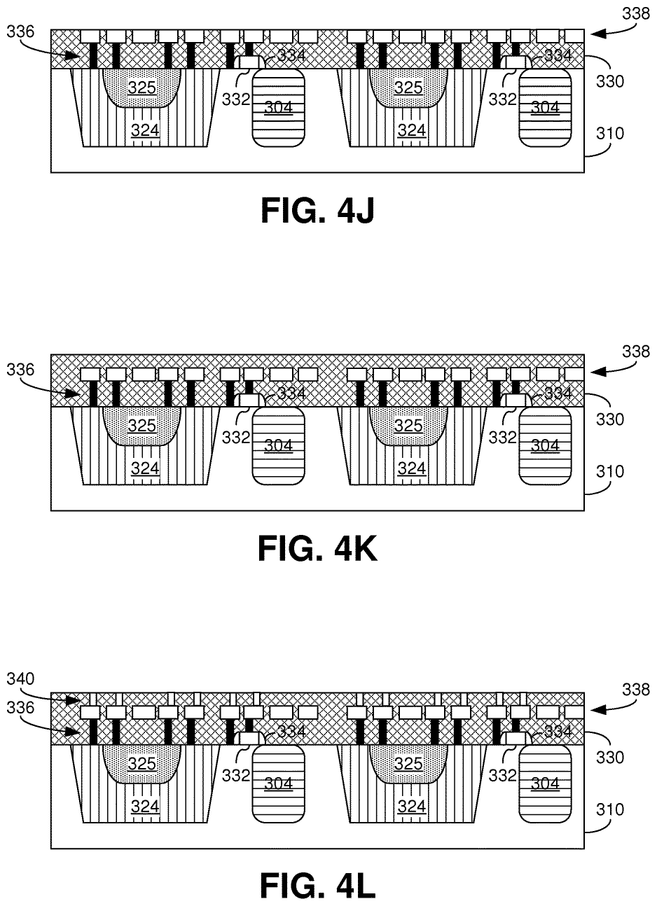

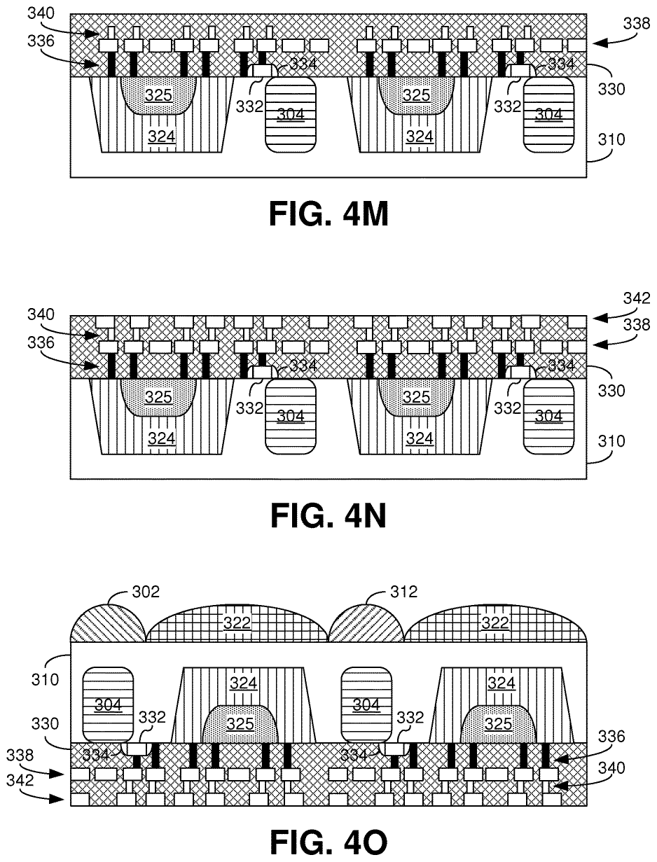

FIGS. 4A-4O illustrate cross-sectional views of some embodiments of a semiconductor structure for the multiple wavelength band light sensor IC 100 at various stages of manufacture. Although FIGS. 4A-4O are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 4A illustrates a portion of the semiconductor substrate 310 that may serve as the base structure upon which additional processing acts, as depicted in FIGS. 4B-4O, may be performed. More specifically, FIGS. 4B-4N illustrate the various processing acts by processing the semiconductor substrate 310 and subsequent layers from above, causing the resulting structure to appear inverted relative to the final structure shown in FIG. 3B.

The semiconductor substrate 310 may be a p-doped silicon (p-Si) substrate, although other materials may be employed in other embodiments. Also, in some embodiments, the semiconductor substrate 310 manifests as a semiconductor wafer, and may have a diameter of 1-inch (25 mm); 2-inch (51 mm); 3-inch (76 mm); 4-inch (100 mm); 5-inch (130 mm) or 125 mm (4.9 inch); 150 mm (5.9 inch, usually referred to as “6 inch”); 200 mm (7.9 inch, usually referred to as “8 inch”); 300 mm (11.8 inch, usually referred to as “12 inch”); or 450 mm (17.7 inch, usually referred to as “18 inch”), for example. After processing is completed (e.g., as described below in connection with FIGS. 4B-4O), such a wafer may be optionally stacked with other wafers and then singulated into individual dice that correspond to individual ICs.

FIG. 4B illustrates forming of the implantation regions 304 in the semiconductor substrate 310 to create the visible light photodiodes discussed above. In some embodiments, a mask 303 is positioned over the semiconductor substrate 310 with gaps or holes defined therethrough. An ion implantation beam 351 may then be directed toward the mask 303 and semiconductor substrate 310 to generate the implantation regions 304 at desired locations throughout the semiconductor substrate 310. In some embodiments, the ion implantation beam 351 creates an n-doped silicon region as the implantation region 304. Also, in some embodiments, a portion of the implantation region 304 may appear as an intrinsic (undoped) semiconductor region (e.g., due to n-doping of a p-doped semiconductor substrate 310). In a plan view of the semiconductor substrate 310, the implantation regions 304 may be distributed in a two-dimensional layout corresponding to the layout of the VL subpixels 212, 214, and 216 of FIG. 2.

FIG. 4C illustrates forming of the gate structure 332 and surrounding sidewall spacer 334 over the semiconductor substrate 310 for each implantation region 304. In some embodiments, each gate structure 332 and associated sidewall spacer 334 is located near or adjacent the corresponding implantation region 304 to facilitate the use of the gate structure 332 as a charge transfer gate, as described above. In some embodiments, the sidewall spacer 334, which may be formed conformally about the gate structure 332, may provide separation between the gate structure 332 and the adjacent contact 333 (shown in FIG. 3B) subsequently formed. In some embodiments, the gate structure 332 may be a polycrystalline silicon (poly-Si) structure.

FIG. 4D illustrates creation (e.g., etching) of cavities 323, where each cavity 323 corresponds with the location of the different semiconductor material 324 associated with each SWIR photodetector. In some embodiments, the cavities 323 are arranged in a two-dimensional layout corresponding to the SWIR subpixels 202 depicted in FIG. 2. In some embodiments, each cavity 323 may appear circular in a plan view of the semiconductor substrate 310. Also, in some embodiments, each cavity 323 may possess an angled sidewall such that each cavity 323 describes an intermediate portion or frustum of an inverted cone. However, other shapes for the cavities 323 are also possible in other embodiments.

FIG. 4E illustrates filling of the cavities 323 with the different semiconductor material 324. As mentioned above, in some embodiments, the different semiconductor material 324 may be germanium (e.g., p-doped germanium), and may be accomplished by epitaxial growth. In some embodiments, germanium may be a more suitable semiconductor material for forming photodetectors (e.g., photodiodes) for sensing IR light 114 (e.g., SWIR light), while silicon may be more suitable for forming photodetectors for sensing visible light 112 (e.g., red, green, and blue wavelengths of light), as described above.

In some embodiments, as described with respect to FIGS. 4B-4E, creation of the implantation regions 304 and forming of the gate structures 332 and associated sidewall spacers 334 may precede the etching and filling of the cavities 323 with the different semiconductor material 324. This order of action may be undertaken in circumstances in which high-temperature processes (e.g., the forming of the gate structures 332 and/or the associated sidewall spacers 334) may involve temperatures that may impose damage upon the different semiconductor material 324. For example, if the different semiconductor material 324 is germanium (with a melting point of approximately 938 degrees Celsius), processes that involve higher temperatures may distort or damage any germanium if the cavities 323 had been filled before such processes.

FIG. 4F illustrates forming of the implantation regions 325 in the different semiconductor material 324 to create the SWIR light photodiodes discussed above. In some embodiments, a mask 313 is positioned over the semiconductor substrate 310 with gaps or holes therethrough coinciding with the regions occupied by the different semiconductor material 324. An ion implantation beam 361 may then be directed toward the mask 313 and semiconductor substrate 310 to generate the implantation regions 325. In some embodiments, the ion implantation beam 361 creates an n-doped germanium region as the implantation region 325. Also, in some embodiments, a portion of the implantation region 325 may appear as an intrinsic (undoped) semiconductor region (e.g., due to n-doping of a p-doped different semiconductor material 324).

FIG. 4G illustrates forming of a layer of dielectric material 330 (e.g., silicon dioxide (SiO₂)) over the semiconductor substrate 310 and associated structures described above as an insulating structure.

FIG. 4H illustrates forming (e.g., etching and subsequent depositing and/or chemical mechanical planarization (CMP)) of contacts 336 within the dielectric material 330 for electrically coupling to various structures (e.g., semiconductor substrate 310, implantation region 304, gate structure 332, different semiconductor material 324, and implantation region 325). As indicated above, contacts 336 include contacts for the gate structures 332, as well as contacts 333 (e.g., for the VL photodiodes) and contacts 335 and 337 (e.g., as anodes and cathodes for the SWIR photodiodes).

Thereafter, FIG. 4I illustrates forming of additional dielectric material 330, and FIG. 4J illustrates forming (e.g., etching and subsequent depositing) of metal structures 338 of a metal (M1) layer within the additional dielectric material 330 of FIG. 4I. FIG. 4K illustrates forming of yet additional dielectric material 330, and FIG. 4L illustrates forming conductive vias 340 (e.g., using etching and deposition and/or CMP) within that dielectric material 330. Subsequently, FIG. 4M illustrates forming of more dielectric material 330 atop the previously assembled structure, and FIG. 4N illustrates forming (e.g., via etching and deposition and/or CMP) metal structures 342 of a second metal (M2) layer. In some embodiments, metal structures 338 and 342 and/or vias 340 may be formed from one or more conductive materials (e.g., copper). Metal structures 338 and 342, as well as vias 340, may collectively form conductive structures (e.g., row and column selection lines, data capturing lines, and so on) for coupling the VL and SWIR photodiode structures with supporting circuitry (e.g., supporting electronics 106 of FIG. 1). The supporting circuitry may include timing circuitry for capturing data from the photodiodes, processing of the received data, interfacing with other circuitry, and the like. Additional layers on the frontside surface of the assembled structure, such as passivating or planarizing layers, may be subsequently formed in some embodiments.

FIG. 4O illustrates coupling the micro-lenses 302, 312, and 322 for the photodiodes over a backside surface of semiconductor substrate 310. Each of the micro-lenses 302, 312, and 322 may be positioned over a corresponding photodiode associated with an implantation region 304 or different semiconductor material 324 and associated implantation region 325. Further, each of the micro-lenses 302, 312, and 322 is configured to direct (and possibly filter) received light (e.g., visible light 112 or IR light 114) downward toward its corresponding photodiode for sensing.

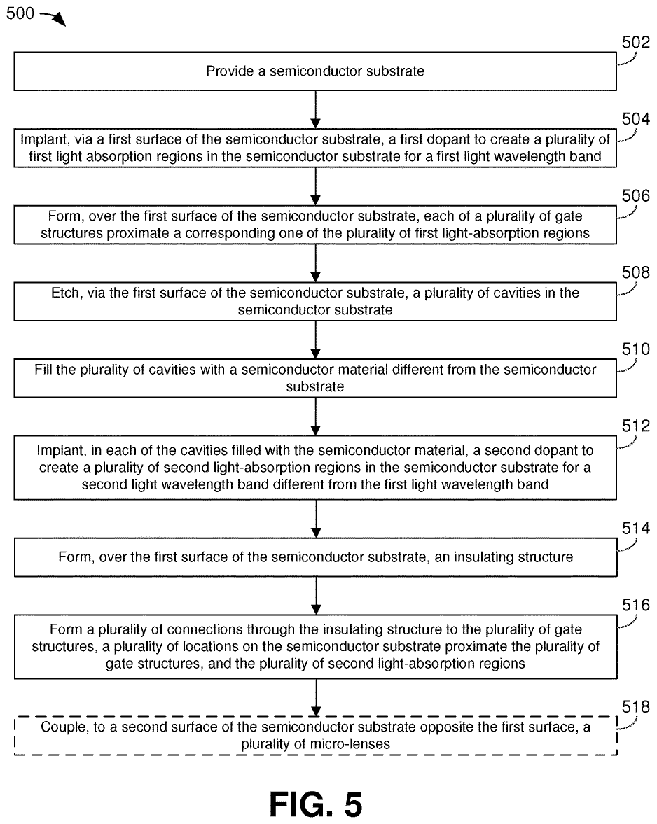

FIG. 5 illustrates a methodology 500 of forming a multiple wavelength band light sensor IC in accordance with some embodiments. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

Acts 502 through 518 may correspond, for example, to the structure previously illustrated in FIGS. 4A through 4O in some embodiments. At Act 502, a semiconductor substrate (e.g., semiconductor substrate 310) may be provided (e.g., as shown at FIG. 4A). At Act 504, via a first (e.g., frontside) surface of the semiconductor substrate, a first dopant may be implanted to create a plurality of first light-absorption regions (e.g., implantation regions 304) in the semiconductor substrate for a first light wavelength band (e.g., a visible light wavelength band) (e.g., as depicted at FIG. 4B). At Act 506, each of a plurality of gate structures (e.g., gate structures 332) may be formed over the first surface of the semiconductor substrate proximate a corresponding one of the plurality of first light-absorption regions (e.g., as illustrated at FIG. 4C). At Act 508, a plurality of cavities (e.g., cavities 323) may be etched in the first surface of the semiconductor substrate (e.g., as shown in FIG. 4D). At Act 510, the plurality of cavities may be filled with a semiconductor material that is different from the semiconductor substrate (e.g., different semiconductor material 324) (e.g., as depicted in FIG. 4E). At Act 512, a second dopant may be implanted in each of the cavities filled with the different semiconductor material to create a plurality of second light-absorption regions (e.g., implantation regions 325) in the semiconductor substrate for a second light wavelength band (e.g., an infrared light wavelength band) different from the first light wavelength band (e.g., as illustrated in FIG. 4F). At Act 514, an insulating structure (e.g., dielectric material 330) is formed over the first surface of the semiconductor substrate (e.g., as shown in FIGS. 4I, 4K, and 4M). At Act 516, a plurality of connections (e.g., contacts 336, metal structures 338 and 342, and vias 340) is formed through the insulating structure to the plurality of gate structures, a plurality of locations on the semiconductor substrate proximate the plurality of gate structures, and the plurality of second light-absorption regions (e.g., as depicted in FIGS. 4H, 4J, 4L, and 4N). Optionally, at Act 518, a plurality of micro-lenses (e.g., micro-lenses 302, 312, and 322) may be coupled to a second (e.g., backside) surface of the semiconductor substrate (e.g., as illustrated in FIG. 4O).

Some embodiments relate to an integrated circuit light sensor device. The integrated circuit light sensor device includes a semiconductor substrate, as well as a plurality of first light-absorption regions and a plurality of second light-absorption regions located in the semiconductor substrate. Each of the first light-absorption regions includes an implantation region of the semiconductor substrate. The implantation region and the semiconductor substrate form at least a portion of a corresponding one of a plurality of first photodetectors for a first light wavelength band. Each of the second light-absorption regions includes a semiconductor material different from the semiconductor substrate. The semiconductor material forms at least a portion of a corresponding one of a plurality of second photodetectors for a second light wavelength band different from the first light wavelength band.

Some embodiments relate to another integrated circuit light sensor device. The integrated light sensor device includes a substrate including a first side surface and a second side surface. The integrated light sensor device also includes an interconnect structure including a dielectric structure, metal lines, and vias disposed over the first side surface, as well as a plurality of first light-absorption regions and a plurality of second light-absorption regions located in the substrate. Each of the first light-absorption regions includes a doped region of the substrate. The doped region and the substrate form at least a portion of a corresponding one of a plurality of first photodetectors for a first visible light wavelength band. Each of the second light-absorption regions includes a germanium region extending from the first side surface to a depth into the substrate. The germanium region forms at least a portion of a corresponding one of a plurality of second photodetectors for a second light wavelength band different from the first visible light wavelength band. In a plan view of the substrate, the plurality of first light-absorption regions are interspersed among the plurality of second light-absorption regions.

Some embodiments relate to a method of manufacturing an integrated circuit light sensor device. The method includes providing a semiconductor substrate and implanting, via a first surface of the semiconductor substrate, a first dopant to create a plurality of first light-absorption regions in the semiconductor substrate for a first light wavelength band. The method also includes etching, via the first surface of the semiconductor substrate, a plurality of cavities in the semiconductor substrate, and filling the plurality of cavities with a semiconductor material different from the semiconductor substrate. The method also includes implanting, in each of the plurality of cavities filled with the semiconductor material, a second dopant to create a plurality of second light-absorption regions in the semiconductor substrate for a second light wavelength band different from the first light wavelength band.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit light sensor device, comprising:
a semiconductor substrate;
a plurality of first light-absorption regions located in the semiconductor substrate, each of the first light-absorption regions comprising an implantation region of the semiconductor substrate, the implantation region and the semiconductor substrate forming at least a portion of a corresponding one of a plurality of first photodetectors for a first light wavelength band; and
a plurality of second light-absorption regions located in the semiconductor substrate, each of the second light-absorption regions comprising a semiconductor material different from the semiconductor substrate and forming at least a portion of a corresponding one of a plurality of second photodetectors for a second light wavelength band different from the first light wavelength band.

2. The integrated circuit light sensor device of claim 1, wherein:
the first light wavelength band comprises a visible light wavelength band; and
the second light wavelength band comprises an infrared light wavelength band.

3. The integrated circuit light sensor device of claim 1, wherein:
the semiconductor substrate and the plurality of first light-absorption regions comprise silicon; and
the plurality of second light-absorption regions comprise germanium.

4. The integrated circuit light sensor device of claim 1, wherein:
each of the plurality of second light-absorption regions is defined by a cavity of the semiconductor substrate in which the semiconductor material is located.

5. The integrated circuit light sensor device of claim 1, wherein the plurality of first light-absorption regions and the plurality of second light-absorption regions are present at a first surface of the semiconductor substrate opposite a second surface at which light enters the semiconductor substrate.

6. The integrated circuit light sensor device of claim 1, wherein:
the plurality of first photodetectors comprises a plurality of first photodiodes; and
each first photodiode of the plurality of first photodiodes comprises a photodiode junction defined by the semiconductor substrate and the implantation region of the first photodiode.

7. The integrated circuit light sensor device of claim 6, further comprising:
a plurality of gate structures disposed over the semiconductor substrate, wherein each of the plurality of gate structures is positioned proximate a corresponding one of the plurality of first photodiodes; and
a plurality of first connections disposed on the semiconductor substrate, wherein each of the plurality of first connections is positioned proximate a corresponding one of the plurality of gate structures.

8. The integrated circuit light sensor device of claim 1, wherein:
the plurality of second photodetectors comprises a plurality of second photodiodes; and
each of the plurality of second photodiodes comprises a photodiode junction defined by the semiconductor material and an implantation region of the semiconductor material.

9. The integrated circuit light sensor device of claim 8, further comprising:
a plurality of anodes, wherein at least one of the plurality of anodes is disposed on the semiconductor material of each of the plurality of second photodiodes; and
a plurality of cathodes, wherein at least one of plurality of cathodes is disposed on the implantation region of the semiconductor material of each of the plurality of second photodiodes.

10. The integrated circuit light sensor device of claim 1, wherein, in a plan view of the semiconductor substrate, each of the plurality of first photodetectors is proximate a corresponding one of the plurality of second photodetectors.

11. The integrated circuit light sensor device of claim 1, wherein, in a plan view of the semiconductor substrate:
the plurality of first photodetectors are organized as a two-dimensional array of a plurality of first pixels, each of the plurality of first pixels comprising four of the plurality of first photodetectors in a first two-by-two configuration; and
the plurality of second photodetectors are organized as a two-dimensional array of a plurality of second pixels, each of the plurality of second pixels comprising four of the plurality of second photodetectors in a second two-by-two configuration.

12. The integrated circuit light sensor device of claim 11, wherein, in the plan view:
for each of the plurality of first pixels, each first photodetector is proximate a corresponding second photodetector of a corresponding one of the plurality of second pixels.

13. An integrated circuit light sensor device, comprising:
a substrate, the substrate including a first side surface and a second side surface;
an interconnect structure including a dielectric structure, metal lines, and vias disposed over the first side surface;
a plurality of first light-absorption regions located in the substrate, each of the first light-absorption regions comprising a doped region of the substrate, the doped region and the substrate forming at least a portion of a corresponding one of a plurality of first photodetectors for a first visible light wavelength band; and
a plurality of second light-absorption regions located in the substrate, each of the second light-absorption regions comprising a germanium region extending from the first side surface to a depth into the substrate and forming at least a portion of a corresponding one of a plurality of second photodetectors for a second light wavelength band different from the first visible light wavelength band; and
wherein, in a plan view of the substrate, the plurality of first light-absorption regions are interspersed among the plurality of second light-absorption regions.

14. The integrated circuit light sensor device of claim 13, further comprising:
a plurality of micro-lenses, each of the plurality of micro-lenses being coupled to the second side surface of the substrate and, in the plan view of the substrate, substantially aligned with a corresponding one of the plurality of first light-absorption regions or a corresponding one of the plurality of second light-absorption regions.

15. A method, comprising:
providing a semiconductor substrate;
implanting, via a first surface of the semiconductor substrate, a first dopant to create a plurality of first light-absorption regions in the semiconductor substrate for a first light wavelength band;
etching, via the first surface of the semiconductor substrate, a plurality of cavities in the semiconductor substrate;
filling the plurality of cavities with a semiconductor material different from the semiconductor substrate; and
implanting, in each of the plurality of cavities filled with the semiconductor material, a second dopant to create a plurality of second light-absorption regions in the semiconductor substrate for a second light wavelength band different from the first light wavelength band.

16. The method of claim 15, further comprising:
forming, over the first surface of the semiconductor substrate after implanting the first dopant, each of a plurality of gate structures proximate a corresponding one of the plurality of first light-absorption regions.

17. The method of claim 16, further comprising:
forming, over the first surface of the semiconductor substrate after implanting the second dopant, an insulating structure; and
forming a plurality of connections through the insulating structure to the plurality of gate structures, a plurality of locations on the semiconductor substrate proximate the plurality of gate structures, and the plurality of second light-absorption regions.

18. The method of claim 17, wherein:
each of the plurality of second light-absorption regions is configured as one of a plurality of second photodiodes for the second light wavelength band; and
for each of the plurality of second photodiodes:
at least a first one of the plurality of connections is configured as an anode; and
at least a second one of the plurality of connections is configured as a cathode.

19. The method of claim 15, wherein:
each of the plurality of first light-absorption regions, in connection with the semiconductor substrate, is configured as one of a plurality of first photodiodes for the first light wavelength band.

20. The method of claim 15, further comprising:
coupling, to a second surface of the semiconductor substrate opposite the first surface, a plurality of micro-lenses, each of the plurality of micro-lenses being aligned, in a plan view of the semiconductor substrate, with a corresponding one of the plurality of first light-absorption regions or a corresponding one of the plurality of second light-absorption regions.
